(19) United States
(12) Patent Application Publication
(10) Pub. No.: US 2023/0360005 A1
(43) Pub. Date: Nov. 9, 2023

(54) WORK DEVICE ANALYSIS SYSTEM AND WORK DEVICE ANALYSIS METHOD, AND DATA COLLECTION DEVICE

(71) Applicant: Panasonic Intellectual Property Management Co.,Ltd., Osaka (JP)

(72) Inventors: ATSUSHI NAKAZONO, Tokyo (JP); HIROFUMI KOGA, Fukuoka (JP); KAZUYUKI YOSHIDOMI, Fukuoka (JP); MANABU OHUCHI, Fukuoka (JP); YUJI NAKAJIMA, Yamanashi (JP); YUTO TAKENAKA, Fukuoka (JP)

(21) Appl. No.: 18/245,137

(22) PCT Filed: Jul. 9, 2021
(86) PCT No.: PCT/JP2021/025982

§ 371 Date: Mar. 13, 2023

(30) Foreign Application Priority Data
Sep. 29, 2020 (JP) 2020-163077

(51) Int. Cl. G06Q 10/20; G06Q 50/04

(52) U.S. Cl. CPC G06Q 10/20; G06Q 50/04

(57) ABSTRACT

A work device analysis method includes acquiring work history information from a work device, the work device being attached with a work unit that performs a work for manufacturing an electronic circuit board (ST1), generating a first file and a second file from the work history information acquired, the first file including an operation event log of the work device, the second file including a manufacturing log of the electronic circuit board (ST2 to ST4), determining maintenance necessity of the work unit based on the first file (ST5), and estimating a state of the work unit based on the second file (ST6).

### TECHNICAL FIELD

The present disclosure relates to a work device analysis system, a work device analysis method, and a data collection device for analyzing a state of a work device for manufacturing an electronic circuit board.

### BACKGROUND ART

In a work unit such as a suction nozzle and a component mounting head to be used in a work device such as a component mounting device for manufacturing an electronic component circuit board, deterioration such as contamination, wear, or distortion occurs in a procedure of repeating a manufacturing work, and a problem such as a decrease in mounting accuracy occurs. Thus, inspection, maintenance, or the like is periodically performed for the work unit. The inspection, maintenance, or the like is performed by interrupting the manufacturing work. Thus, in order to suppress a decrease in production efficiency, it is desirable to execute the inspection, maintenance, or the like at an appropriate timing with a small number of times of execution.

PTL 1 discloses that log data such as a correction amount of a suction position when a suction nozzle picks up an electronic component and an error occurrence event in which the suction nozzle fails to suck the component is collected during an operation of a component mounting device and whether or not there is a malfunction in a work device is diagnosed by a facility diagnosis system when the log data is accumulated by a certain amount. Necessity of maintenance is determined from the diagnosis result, and a maintenance work is instructed. As a result, it is possible to perform maintenance without interrupting a manufacturing work by appropriately diagnosing the malfunction of the work device.

### CITATION LIST

### Patent Literature

PTL 1: Unexamined Japanese Patent Publication No. 2020-27329

### SUMMARY OF THE INVENTION

However, in the related art including PTL 1, although the malfunction of the work device can be diagnosed without interrupting the manufacturing work, the log data to be used for diagnosis is enormous. Accordingly, in a case where a device to be diagnosed is installed in a facility different from the work device, there is a problem that a large load is generated in transmission and reception of data.

Therefore, an object of the present disclosure is to provide a work device analysis system, a work device analysis method, and a data collection device capable of appropriately analyzing a state of a work device.

A work device analysis system of the present disclosure includes an acquisition unit that acquires work history information from a work device, the work device being attached with a work unit that performs a work for manufacturing an electronic circuit board, a file generator that generates a first file and a second file from the work history information acquired, the first file including an operation event log of the work device, the second file including a manufacturing log of the electronic circuit board, a maintenance necessity determination unit that determines maintenance necessity of the work unit based on the first file, and a condition estimation unit that estimates a condition of the work unit based on the second file.

A work device analysis method of the present disclosure includes acquiring work history information from a work device, the work device being attached with a work unit that performs a work for manufacturing an electronic circuit board, generating a first file and a second file from the work history information acquired, the first file including an operation event log of the work device, the second file including a manufacturing log of the electronic circuit board, determining maintenance necessity of the work unit based on the first file, and estimating a condition of the work unit based on the second file.

A data collection device of the present disclosure includes an acquisition unit that acquires work history information from a work device, the work device being attached with a work unit that performs a work for manufacturing an electronic circuit board, a file generator that generates a first file and a second file from the work history information acquired, the first file including an operation event log of the work device, the second file including a manufacturing log of the electronic circuit board, and a transmission unit that transmits the first file and the second file.

According to the present disclosure, the state of the work device can be appropriately analyzed.

### BRIEF DESCRIPTION OF THE DRAWINGS

FIG. 1 is an explanatory diagram of a configuration of a work device analysis system according to an exemplary embodiment of the present disclosure.

FIG. 2 is an explanatory diagram of a configuration of a component mounting device according to the exemplary embodiment of the present disclosure.

FIG. 3 is a block diagram illustrating a configuration of a work device analysis system according to the exemplary embodiment of the present disclosure.

FIG. 4 is a flowchart of a work device analysis method according to the exemplary embodiment of the present disclosure.

### DESCRIPTION OF EMBODIMENT

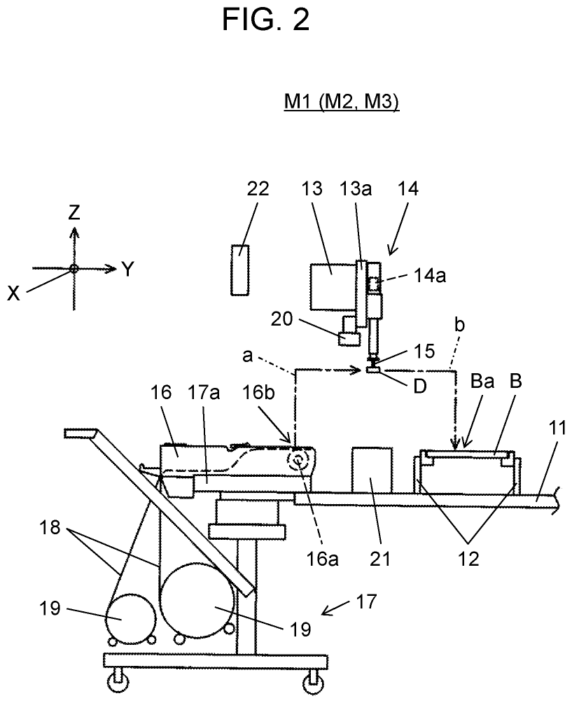

Hereinafter, an exemplary embodiment of the present disclosure will be described in detail with reference to the drawings. Configurations, shapes, and the like to be described below are examples for description, and can be appropriately changed in accordance with specifications of a work device analysis system, a component mounting line, a component mounting device, a component supply device, and the like. Hereinafter, components identical or corresponding to one another throughout all the drawings are denoted by identical reference marks, and overlapped description thereof will be omitted. In FIG. 2, an X axis (a direction perpendicular to paper in FIG. 2) in a board conveyance direction and a Y axis (a left-right direction in FIG. 2) orthogonal to the board conveyance direction are illustrated as two axes orthogonal to each other in a horizontal plane. In addition, a Z axis (an up-down direction in FIG. 2) is illustrated as a height direction orthogonal to the horizontal plane.

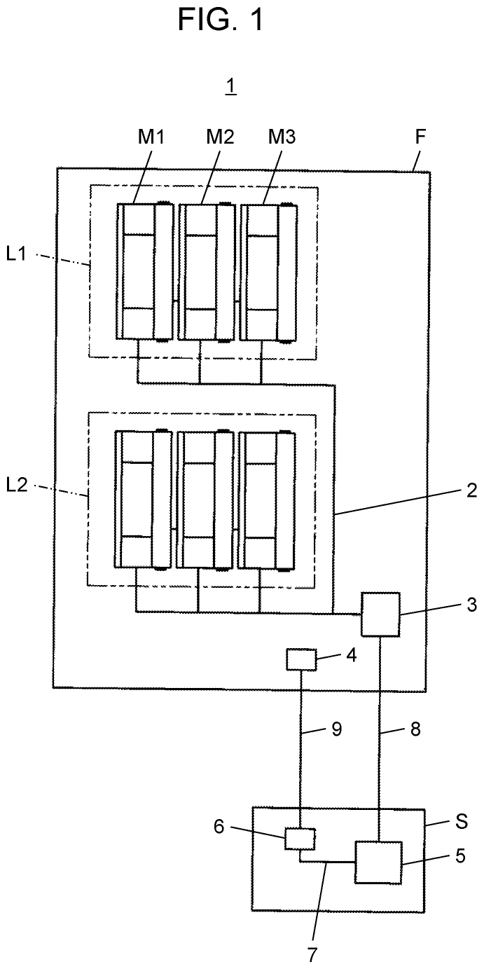

First, a configuration of work device analysis system 1 will be described with reference to FIG. 1. FIG. 1 is an explanatory diagram of a configuration of work device analysis system 1 according to an exemplary embodiment of the present disclosure. Work device analysis system 1 includes factory F and support center S opened at a place away from factory F. In factory F, two component mounting lines L1 and L2 each constructed by connecting a plurality of component mounting devices M1 to M3 are installed. Each of component mounting lines L1 and L2 has a function of manufacturing an electronic circuit board while sequentially mounting electronic components (hereinafter, referred to as “components D”. see FIG. 2) on a circuit board by component mounting devices M1 to M3.

Each of component mounting devices M1 to M3 is connected to manufacturing management device 3 via local area communication network 2 such as a local area network (LAN). In addition, factory F also includes mail reception device 4 that receives an e-mail transmitted from support center S. Note that, the number of component mounting lines L1 and L2 installed in factory F is not necessarily two, and may be one or three or more. In addition, the number of component mounting devices M1 to M3 constituting component mounting lines L1 and L2 is not necessarily three, and may be one, two, or four or more. In addition to manufacturing management device 3, a line management device that manages manufacturing of the electronic circuit board in component mounting lines L1 and L2 may be provided for each of component mounting lines L1 and L2.

In FIG. 1, support center S is opened at a position where it is possible to efficiently execute analysis of necessity of maintenance of a work unit for a plurality of factories F (customers) and various kinds of support for persons in charge of each factory F. Maintenance management device 5 and mail server 6 are provided in support center S.

Mail server 6 is connected to maintenance management device 5 via local area communication network 7 such as a LAN. Manufacturing management device 3 and maintenance management device 5 exchange information via wide area communication network 8 such as the Internet or a mobile communication line. Mail reception device 4 and mail server 6 exchange information such as an e-mail via wide area communication network 9.

Note that, wide area communication network 8 and wide area communication network 9 may share the same wide area communication network. In addition, manufacturing management device 3 and maintenance management device 5 may exchange information via a cloud instead of directly exchanging information. That is, information transmitted from manufacturing management device 3 and maintenance management device 5 may be stored in the cloud, and information may be transmitted from the cloud to manufacturing management device 3 and maintenance management device 5 in accordance with a request. In addition to e-mail, information may be notified by a communication tool using a data communication line, or information may be exchanged by accessing from manufacturing management device 3 or touch panel 22 (see FIG. 2) of component mounting devices M1 to M3.

Next, the configuration of component mounting devices M1 to M3 will be described with reference to FIG. 2. FIG. 2 is an explanatory diagram of a configuration of component mounting device M1 (M2, M3) according to the exemplary embodiment of the present disclosure. Component mounting devices M1 to M3 have similar configurations. Hereinafter, component mounting device M1 will be described.

Component mounting device M1 is a work device having a function of attaching component D on circuit board B. Board conveyance mechanism 12 provided on an upper surface of base 11 conveys circuit board B from a positive direction to a negative direction of the X axis to position and hold the circuit board. Head movement mechanism 13 provided above base 11 moves mounting head 14 detachably attached via plate 13a in the positive and negative directions of the X axis and positive and negative directions of the Y axis. Suction nozzle 15 is detachably attached to a lower end of mounting head 14.

A plurality of tape feeders 16 are attached side by side along the X axis on feeder base 17a provided on an upper portion of carriage 17 coupled to base 11 on a side of board conveyance mechanism 12. A plurality of slots for attaching tape feeder 16 are provided in feeder base 17a. A feeder address is set in each of the plurality of slots for attaching tape feeder 16. Carriages 17 are attached to component mounting device M1 at feeder arrangement positions (positive and negative directions of the Y axis in FIG. 2) provided in front of and behind the component mounting device. In component mounting device M1, an attachment position of tape feeder 16 can be specified by the feeder arrangement position and the feeder address provided in front of and behind the component mounting device.

Carrier tape 18 for storing component D supplied to component mounting device M1 is wound and stored on reels 19 and is held in carriage 17. Carrier tape 18 inserted into tape feeder 16 is fed at regular intervals by tape feeding mechanism 16a incorporated in tape feeder 16. As a result, components D stored in carrier tape 18 are sequentially supplied toward component supply port 16b provided in an upper portion of tape feeder 16.

In a component mounting operation, mounting head 14 moves above tape feeder 16 by head movement mechanism 13, and component D supplied to component supply port 16b of tape feeder 16 is vacuum-sucked and picked up by suction nozzle 15 (arrow a in FIG. 2). Mounting head 14 holding component D moves above circuit board B held by board conveyance mechanism 12 by head movement mechanism 13, and mounts component D at predetermined component mounting position Ba on circuit board B (arrow b in FIG. 2).

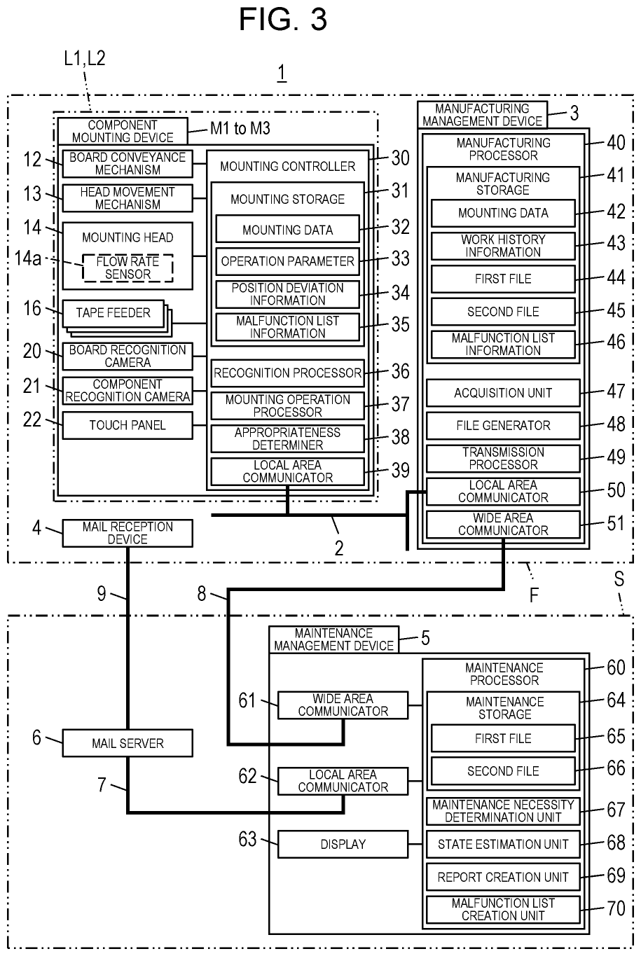

In FIG. 2, board recognition camera 20 whose optical axis is directed in the negative direction of the Z axis is attached to plate 13a. Board recognition camera 20 moves in the positive and negative directions of the X axis and the positive and negative directions of the Y axis integrally with mounting head 14 by head movement mechanism 13. Board recognition camera 20 moves above tape feeder 16 and captures component D supplied to component supply port 16b. Recognition processor 36 (see FIG. 3) performs image recognition on the capturing result, and calculates a supply position deviation amount deviated from a (predetermined) normal supply position at which component D supplied to component supply port 16b is expected to be supplied. A suction position (a stop position of mounting head 14) when suction nozzle 15 picks up component D is corrected based on the calculated supply position deviation amount. In addition, recognition processor 36 also detects a supply error in which component D cannot be recognized since component D is not supplied to component supply port 16b.

In FIG. 2, mounting head 14 includes flow rate sensor 14a that measures a flow rate of air flowing in from suction nozzle 15. When suction nozzle 15 normally sucks component D, the amount of air flowing in from suction nozzle 15 decreases, and a vacuum pressure of suction nozzle 15 decreases. On the other hand, in a case where suction nozzle 15 cannot hold component D or a suction mistake occurs such as suction in an abnormal posture, air flows in from suction nozzle 15. Thus, the vacuum pressure of suction nozzle 15 does not decrease.

The presence or absence of the occurrence of the suction mistake (suction error) is detected from the measurement result of the flow rate of the air by flow rate sensor 14a. Note that, a vacuum gauge (pressure gauge) may be provided instead of flow rate sensor 14a, and the presence or absence of the occurrence of the suction mistake (suction error) may be determined from the measurement result of the vacuum pressure by the vacuum gauge. In addition, the flow rate of the air flowing from suction nozzle 15 after the component mounting is measured by flow rate sensor 14a, and thus, a mounting error in which mounting head 14 carries component D back without being able to mount component D on circuit board B is detected.

In FIG. 2, component recognition camera 21 whose optical axis is directed upward is attached to the upper surface of base 11 between board conveyance mechanism 12 and tape feeder 16. When suction nozzle 15 that picks up component D passes above, component recognition camera 21 captures a lower surface of component D (or, suction nozzle 15 that cannot hold component D) held by suction nozzle 15. Recognition processor 36 performs the image recognition on the capturing result, and determines whether the posture of component D held by suction nozzle 15 is normal or abnormal or whether or not a recognition error in which component D that needs to be held by suction nozzle 15 cannot be recognized occurs. Note that, component recognition camera 21 may capture a side surface in addition to the lower surface of component D.

In addition, recognition processor 36 performs the image recognition on the capturing result, and calculates a suction position deviation amount of component D held by suction nozzle 15 attached to component mounting device M1 (work device) from a normal holding position that is an expected (predetermined) normal suction position. When component D is mounted on component mounting position Ba on circuit board B, mounting position correction and mounting posture correction are executed based on the suction position deviation amount.

In FIG. 2, touch panel 22 operated by an operator is installed at a position where the operator operates on a front surface of component mounting device M1. Various kinds of information are displayed on a display of touch panel 22. In addition, the operator inputs data or operates component mounting device M1 or the like by using an operation button or the like that is an input unit displayed on the display.

Mounting head 14, suction nozzle 15, and tape feeder 16 are appropriately selected in accordance with the type of component D to be mounted on circuit board B and is attached to component mounting device M1. As described above, mounting head 14 that mounts component D on circuit board B, suction nozzle 15 that is attached to mounting head 14 and sucks component D, or tape feeder 16 (component supply device) that supplies component D to mounting head 14 is a work unit that is attached to component mounting device M1 (work device) and performs a work for manufacturing the electronic circuit board.

Next, a configuration of work device analysis system 1 will be described with reference to FIG. 3. FIG. 3 is a block diagram illustrating a configuration of work device analysis system 1. Component mounting devices M1 to M3 (work devices) included in component mounting lines L1 and L2 have similar configurations. Hereinafter, component mounting device M1 of component mounting line L1 will be described.

In FIG. 3, component mounting device M1 includes mounting controller 30, board conveyance mechanism 12, head movement mechanism 13, mounting head 14, tape feeder 16, board recognition camera 20, component recognition camera 21, and touch panel 22. Mounting controller 30 includes mounting storage 31, recognition processor 36, mounting operation processor 37, appropriateness determiner 38, and local area communicator 39. Local area communicator 39 transmits and receives data to and from other component mounting devices M2 and M3 and manufacturing management device 3 via local area communication network 2. Mounting storage 31 is a storage device, and stores mounting data 32, operation parameter 33, position deviation information 34, malfunction list information 35, and the like.

Mounting data 32 is created for each type of electronic circuit board to be manufactured, and includes data such as a component type, a size, and component mounting position Ba (XY coordinates) of component D to be mounted on circuit board B. Mounting data 32 stored in mounting storage 31 of component mounting device M1 includes at least data necessary for a component mounting work in the work device. Recognition processor 36 performs image recognition on a capturing result of component supply port 16b of tape feeder 16 by board recognition camera 20, calculates a correction value of the suction position of suction nozzle 15, and stores the correction value as operation parameter 33 in mounting storage 31.

In FIG. 3, recognition processor 36 performs image recognition on a capturing result of component D held by suction nozzle 15 by component recognition camera 21, calculates the suction position deviation amount from the normal holding position, and stores the calculated suction positional deviation amount as position deviation information 34 in mounting storage 31. In addition, recognition processor 36 calculates component mounting position Ba and a correction value of a mounting posture when component D is mounted on circuit board B based on the suction position deviation amount, and stores calculated component mounting position Ba and correction value of the mounting posture as operation parameter 33 in mounting storage 31.

In addition, recognition processor 36 performs the image recognition on the imaging result and detects a supply error, a recognition error, or the like. Recognition processor 36 creates a manufacturing log in which information specifying tape feeder 16 in which the supply error is detected, the component type of component D supplied, and carrier tape 18 is associated with the detected supply error, and transmits the manufacturing log as work history information to manufacturing management device 3. In addition, recognition processor 36 creates a manufacturing log in which information specifying component D that is not held, suction nozzle 15 that cannot be held, and mounting head 14 is associated with the detected recognition error, and transmits the manufacturing log as the work history information to manufacturing management device 3.

In FIG. 3, mounting operation processor 37 controls board conveyance mechanism 12, head movement mechanism 13, mounting head 14, and tape feeder 16 based on mounting data 32, operation parameter 33, and position deviation information 34 stored in mounting storage 31 to execute the component mounting operation. In addition, whenever component D is mounted on circuit board B, mounting operation processor 37 transmits, as the work history information, a manufacturing log associated with a correction value (operation parameter 33) used for component D and the component mounting operation, a flow rate value of flow rate sensor 14a when component D is sucked, a pressure value of the vacuum gauge when component D is sucked, a current value when tape feeder 16 is operated, and the like to manufacturing management device 3.

In addition, when the work error is detected during the component mounting operation, mounting operation processor 37 transmits, as the work history information, a manufacturing log associated with a content and an occurrence time of a work error and the like to manufacturing management device 3. Examples of the work error include a suction error in which suction nozzle 15 cannot suck component D, a recognition error in which component D sucked and held by suction nozzle 15 cannot be recognized by component recognition camera 21, a mounting error in which mounting head 14 carries component D back without being able to mount component D on circuit board B, and a supply error in which component D supplied by tape feeder 16 (component supply device) cannot be recognized by board recognition camera 20. Note that, in a case where component mounting lines L1 and L2 include a mounting inspection device that inspects component D mounted on circuit board B in addition to component mounting devices M1 to M3, mounting operation processor 37 may detect the mounting error based on the presence or absence of component D inspected by the mounting inspection device, the position deviation amount, or the like.

In addition, when an operation event such as a work stop event for temporarily stopping the component mounting operation due to the work error or the like or a work restart event for restarting the component mounting operation after an error recovery work by the operator occurs, mounting operation processor 37 transmits, as the work history information, an operation event log associated with a content and an occurrence time of the operation event and the like to manufacturing management device 3. The operation event log of the work stop event includes, as details of the work error causing the work stop, information specifying the work unit such as the related tape feeder 16, mounting head 14, and suction nozzle 15.

In FIG. 3, manufacturing management device 3 includes manufacturing processor 40. Manufacturing processor 40 includes manufacturing storage 41, acquisition unit 47, file generator 48, transmission processor 49, local area communicator 50, and wide area communicator 51.

Local area communicator 50 transmits and receives data to and from component mounting devices M1 to M3 of component mounting lines L1 and L2 via local area communication network 2. Wide area communicator 51 transmits and receives data to and from maintenance management device 5 installed in support center S via wide area communication network 8. Manufacturing storage 41 is a storage device, and stores mounting data 42, work history information 43, first file 44, second file 45, malfunction list information 46, and the like.

In FIG. 3, mounting data 42 stored in manufacturing storage 41 is data similar to mounting data 32 stored in mounting storage 31 of component mounting device M1 described above. However, mounting data 42 includes data necessary for the component mounting works of all component mounting devices M1 to M3 included in component mounting lines L1 and L2.

Acquisition unit 47 sequentially acquires work history information transmitted from each of component mounting devices M1 to M3 (work devices) included in component mounting lines L1 and L2, and stores the work history information as work history information 43 in manufacturing storage 41.

Acquisition unit 47 collects the work history information from the line management device at predetermined time intervals such as a time when the type of the electronic circuit board to be manufactured is changed or a shift change time of the operator from devices other than component mounting devices M1 to M3. Examples of the device that collects data from devices other than component mounting devices M1 to M3 include a line management device having a function of collecting work history information for each of component mounting lines L1 and L2, a production scheduler that stores a production plan or a worker shift, and a production simulator that estimates an optimal production plan. That is, acquisition unit 47 acquires work history information 43 while the work device is operating or at predetermined time intervals.

In addition, acquisition unit 47 also collects maintenance history information that is a result of maintenance of the work unit. The maintenance history information may be input by the operator, or a maintenance work result by an automatic maintenance work unit (not illustrated) that automatically performs a maintenance work may be collected as the maintenance history information. In addition, as the maintenance history information, a maintenance result executed by support center S located away from factory F may be acquired. Note that, examples of the automatic maintenance work unit include a nozzle cleaning unit that cleans a nozzle provided in mounting head 14, a feeder maintenance unit that adjusts a feeding mechanism of tape feeder 16, and a head maintenance unit that inspects or adjusts slidability of mounting head 14. Note that, in addition to the work result, the maintenance history information may include identification information of the work unit, a maintenance execution date and time, an execution place, the number of times of maintenance execution, and clearing of the work history information.

In FIG. 3, file generator 48 creates first file 44 including operation event logs and maintenance history information of component mounting devices M1 to M3 (work devices) from mounting data 42 and work history information 43 stored in manufacturing storage 41. In addition, file generator 48 generates second file 45 including a manufacturing log of the electronic circuit board from mounting data 42 and work history information 43 stored in manufacturing storage 41.

The manufacturing log of the electronic circuit board included in work history information 43 collected from component mounting devices M1 to M3 includes the number of times of mounting of component D, and the number of times of the recognition error, the suction error, the mounting error, the supply error, and the like in which the mounting of component D is mistaken in component mounting devices M1 to M3 for mounting component D on the electronic circuit board. In addition, the manufacturing log of the electronic circuit board includes position deviation information 34 of component D held by suction nozzle 15 attached to component mounting devices M1 to M3 from the normal holding position. Further, the manufacturing log of the electronic circuit board includes the size of component D mounted on the electronic circuit board.

In FIG. 3, file generator 48 generates second file 45 including the manufacturing log of the electronic circuit board. For example, file generator 48 generates second file 45 including information obtained by totaling the number of times of mounting of component D and the number of times of mounting mistakes of component D for each combination of the work units such as tape feeder 16, mounting head 14, and suction nozzle 15. Note that, second file 45 may include an error rate calculated based on the number of times of mistakes and the number of times of suction in addition to a total value of various numbers of times in each predetermined period (for example, every day).

In addition, file generator 48 statistically processes a correction amount of the suction position of suction nozzle 15 when component D is taken out from tape feeder 16, a correction amount of the mounting position of suction nozzle 15 when component D is mounted on circuit board B, and the like, and generates second file 45 including information obtained by calculating a moving average, a standard deviation, or the like. That is, file generator 48 generates second file 45 by statistically processing the manufacturing log of the electronic circuit board. The manufacturing log of the electronic circuit board is created for each component mounting position Ba of circuit board B of the electronic circuit board manufactured by mounting several hundred to several thousands of components. Thus, a data amount of the manufacturing log of the electronic circuit board is enormous. On the other hand, a data amount of information created by statistically processing the manufacturing log of the electronic circuit board is significantly smaller than an original data amount.

In FIG. 3, file generator 48 creates second file 45 including information obtained by totalizing sizes such as a length, a width, and a thickness of component D mounted on the electronic circuit board from mounting data 42. Similarly to the information generated by statistically processing the manufacturing log of the electronic circuit board, a data amount of a size of component D collected from mounting data 42 is significantly smaller than the original data amount. In addition, leakage of customer information can be prevented by creating the second file by extracting only information on the size of component D necessary for performance estimation processing of the work unit from mounting data 42 including the customer information.

In FIG. 3, transmission processor 49 causes maintenance management device 5 to transmit first file 44 and second file 45 generated by file generator 48 via wide area communicator 51. That is, transmission processor 49 and wide area communicator 51 are transmission units that transmit first file 44 and second file 45 to maintenance management device 5. File generator 48 generates first file 44 and second file 45 at a preset time such as a predetermined time once a week. Transmission processor 49 transmits generated first file 44 and second file 45 to maintenance management device 5. That is, first file 44 and second file 45 are transmitted to maintenance management device 5 at a preset time (For example, 8:00 on every Wednesday).

In FIG. 3, maintenance management device 5 includes maintenance processor 60, wide area communicator 61, local area communicator 62, and display 63. Maintenance processor 60 includes maintenance storage 64, maintenance necessity determination unit 67, state estimation unit 68, report creation unit 69, and malfunction list creation unit 70. Maintenance storage 64 is a storage device, and stores first file 65, second file 66, and the like.

Wide area communicator 61 transmits and receives data to and from manufacturing management device 3 installed in factory F via wide area communication network 8. Local area communicator 62 transmits and receives data to and from mail server 6 via local area communication network 7. Display 63 is a display device such as a liquid crystal panel to display various kinds of data, information, and the like.

First file 44 and second file 45 transmitted from manufacturing management device 3 of factory F are received in maintenance storage 64 via wide area communicator 61. Received first file 44 and second file 45 are stored as first file 65 and second file 66 in association with information specifying factory F or manufacturing management device 3 as a transmission source in maintenance storage 64. Maintenance storage 64 accumulates not only latest information transmitted from manufacturing management device 3 but also information of a predetermined period including information transmitted last time. In addition, not only one factory F but also a plurality of factories F periodically transmit first file 44 and second file 45 to maintenance management device 5 installed in support center S.

In FIG. 3, maintenance necessity determination unit 67 determines maintenance necessity of the work units (tape feeder 16, mounting head 14, suction nozzle 15, and the like) from first file 65 stored in maintenance storage 64. Specifically, maintenance necessity determination unit 67 determines that maintenance (maintenance) is necessary for a work unit of which the cumulative number of times of the number of times related to the work stop event or the total number of times of the predetermined period exceeds a predetermined determination reference number of times.

In FIG. 3, state estimation unit 68 executes state estimation processing of estimating a state of the work unit from second file 66 stored in maintenance storage 64. Specifically, state estimation unit 68 estimates that the work unit is malfunctioning or is becoming malfunctioning from various kinds of information included in second file 66, and determines whether or not an inspection for determining necessity of maintenance of the work unit is necessary. For example, in a case where an error rate for each predetermined period tends to increase, in a case where the error rate does not increase but the correction amount tends to increase, or in a case where a variation (standard deviation) in the correction amount becomes larger than a determination reference, state estimation unit 68 determines that the inspection of the work unit is necessary. The predetermined period is, for example, the number of days elapsed from a previous maintenance execution date and time or shipment (delivery). The number of days is set in units of date, week, month, and year by each work unit.

In addition, state estimation unit 68 may estimate the malfunction of the work unit by using a malfunction diagnosis model created in advance by machine learning based on a parameter included in second file 66 and an error occurrence situation (such as the number of times or frequency). In addition, in a case where the tendency of the malfunction becomes apparent, for example in a case where component D is large or small based on the size of component D included in second file 66, state estimation unit 68 associates information on the size of component D (a range of a recommended size or the like) with information on the determined inspection of the work unit.

In FIG. 3, report creation unit 69 creates a report to be transmitted to an administrator of factory F based on information on the work unit that requires maintenance determined by maintenance necessity determination unit 67 or information on the work unit that requires inspection due to the malfunction estimated by state estimation unit 68. The report includes information specifying a work unit that requires maintenance or inspection, a reason for requiring maintenance or inspection, and a recommended inspection method such as cleaning in the case of inspection. The report created by report creation unit 69 is transmitted to mail server 6 via local area communicator 62. Mail server 6 transmits the report as an e-mail to a designated destination at a preset time. The e-mail transmitted from mail server 6 is received by mail reception device 4 installed in factory F.

In FIG. 3, malfunction list creation unit 70 creates a list of malfunctioning work units (malfunction list) based on the information on the work unit that requires maintenance determined by maintenance necessity determination unit 67 or the information on the work unit that requires inspection due to the malfunction estimated by state estimation unit 68. The malfunction list includes the information specifying the work unit that requires inspection or maintenance, the reason why component D is estimated to be malfunctioning, and usage restriction items such as a range of a size of the recommended component D. The malfunction list created by malfunction list creation unit 70 is transmitted to manufacturing management device 3 of factory F via wide area communicator 61.

Note that, in a case where component mounting devices M1 to M3 include the work unit that requires inspection or maintenance, information on the malfunction list also includes a place where the work unit is provided, the place being specified from the information on the manufacturing log from component mounting devices M1 to M3. In addition, the malfunction list created based on maintenance necessity determination unit 67 and the malfunction list created based on state estimation unit 68 may be present in the malfunction list. In that case, since the work unit requires inspection or maintenance soon, the malfunction list created based on state estimation unit 68 can be used to create a maintenance plan. In addition, since the malfunction list created based on maintenance necessity determination unit 67 requires inspection or maintenance of the work unit, the malfunction list can be used to create a production plan not to be used for production.

Manufacturing management device 3 stores the received malfunction list as malfunction list information 46 in manufacturing storage 41, and transmits the malfunction list to component mounting devices M1 to M3 (work devices) of component mounting lines L1 and L2. The malfunction lists received by component mounting devices M1 to M3 are stored as malfunction list information 35 in mounting storage 31.

In FIG. 3, appropriateness determiners 38 of component mounting devices M1 to M3 determine whether or not the work units attached to component mounting devices M1 to M3 are included in malfunction list information 35 during a set-up change for changing the type of the electronic circuit board to be manufactured, the start of production, the end of production, or the like. In a case where the attached work unit is included in malfunction list information 35, appropriateness determiner 38 displays a warning on touch panel 22. The warning includes, for example, the reason why the work unit is estimated to be malfunctioning, recommended inspection contents, or recommendation of replacement with another work unit. In addition, the warning may be notified and the use may be determined by the operator, or the interlock may be automatically performed not to be used. Note that, a plurality of analyses of maintenance necessity and malfunction estimation are used in combination, and thus, it is possible to further suppress production stop due to the malfunction of the work unit.

As described above, manufacturing management device 3 is a data collection device including acquisition unit 47 that acquires work history information 43 from the work devices (component mounting devices M1 to M3) to which the work units (tape feeder 16, mounting head 14, and suction nozzle 15) that perform the work for manufacturing the electronic circuit board are attached, file generator 48 that generates first file 44 including the operation event log and the maintenance history information of the work device and second file 45 including the manufacturing log of the electronic circuit board from acquired work history information 43, and the transmission unit (transmission processor 49 or wide area communicator 51) that transmits first file 44 and second file 45.

In addition, maintenance management device 5 including maintenance necessity determination unit 67 is a maintenance necessity determination device that determines the maintenance necessity of the work unit from first file 65. In addition, maintenance management device 5 including state estimation unit 68 is a state estimation device that estimates a state of the work unit from second file 66. The transmission unit of the data collection device (manufacturing management device 3) transmits first file 44 to the maintenance necessity determination device, and transmits second file 45 to the state estimation device.

As described above, manufacturing management device 3 can reduce a load required for transmission and reception of data by extracting and processes information necessary for analysis processing, creating first file 44 and second file 45 having a small data amount, and then transmitting the first file 44 and the second file 45 to maintenance management device 5 (the maintenance necessity determination device and the state estimation device). As a result, even though the maintenance necessity determination device and the state estimation device that analyze states of the work device and the work unit are installed in a facility different from factory F in which the work device is installed, the state of the work device can be appropriately analyzed.

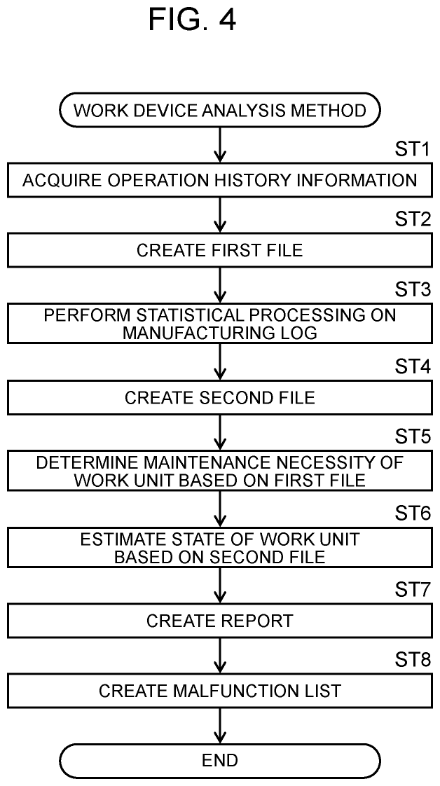

Next, a work device analysis method for analyzing the state of the work unit to which the work devices (component mounting devices M1 to M3) are attached will be described along a flow of FIG. 4. FIG. 4 is a flowchart of the work device analysis method according to the exemplary embodiment of the present disclosure.

First, acquisition unit 47 acquires work history information 43 and mounting data 32 from the work devices (component mounting devices M1 to M3) to which the work units (tape feeder 16, mounting head 14, and suction nozzle 15) are attached (ST1).

Work history information 43 is acquired while the work device is operating or at predetermined time intervals. Subsequently, file generator 48 generates first file 44 including the operation event log and the maintenance history information of the work device from acquired work history information 43 (ST2).

Subsequently, file generator 48 statistically processes the manufacturing log of the electronic circuit board included in acquired work history information 43 (ST3).

Subsequently, file generator 48 generates second file 45 including the manufacturing log of the electronic circuit board from the acquired work history information 43 and mounting data 32, and the statistical processing result of the statistical processing (ST4). First file 44 and second file 45 are transmitted to maintenance management device 5 and are stored as first file 65 and second file 66 in maintenance storage 64.

Subsequently, maintenance necessity determination unit 67 determines the maintenance necessity of the work unit from first file 65 (ST5).

Subsequently, state estimation unit 68 estimates the state of the work unit from second file 66 (ST6). As a result, the state of the work device can be appropriately analyzed.

In FIG. 4, subsequently, report creation unit 69 creates a report including information specifying the work unit that requires maintenance or inspection, a recommended inspection method, and the like based on the information on the determined work unit requiring maintenance and the information on the work unit requiring inspection due to the estimated malfunction (ST7). The created report is transmitted to mail reception device 4 of factory F as an e-mail.

Subsequently, malfunction list creation unit 70 creates a malfunction list including information specifying the work unit that requires inspection or maintenance and the like based on the information on the determined work unit that requires maintenance and the information on the work unit that requires inspection due to the estimated malfunction (ST8). The malfunction list is transmitted to manufacturing management device 3 of factory F, and is used for warning or the like when the work units included in the malfunction list are attached to the work devices (component mounting devices M1 to M3).

As described above, work device analysis system 1 according to the present exemplary embodiment includes acquisition unit 47 that acquires work history information 43 from the work devices (the component mounting devices M1 to M3) to which the work units (tape feeder 16, mounting head 14, and suction nozzle 15) that perform the work for manufacturing the electronic circuit board are attached, file generator 48 that generates first file 44 including the operation event log and the maintenance history information of the work device and second file 45 including the manufacturing log of the electronic circuit board from acquired work history information 43, maintenance necessity determination unit 67 that determines the maintenance necessity of the work unit from first file 65 (first file 44), and state estimation unit 68 that estimates the state of the work unit from second file 66 (second file 45). As a result, the state of the work device can be appropriately analyzed.

Note that, examples of the machine learning related to the present exemplary embodiment include supervised learning for learning a relationship between an input and an output by using supervised data in which a label (output information) is given to input information, unsupervised learning for constructing a structure of data only from an unlabeled input, semi-supervised learning for handling both labeled and unlabeled inputs, and reinforcement learning for learning a behavior that can obtain the most feedback by obtaining feedback for a behavior selected from an observation result of a state. In addition, specific methods of machine learning include a neural network (including deep learning using a multilayer neural network), genetic programming, a decision tree, a Bayesian network, and a support vector machine (SVM).

In the above description, the example in which the work history information is transmitted from the work device to which the work unit that performs the work for manufacturing the electronic circuit board is attached to maintenance necessity determination 67 to determine the maintenance necessity of the work unit and is transmitted to state estimation unit 68 to estimate the state of the work unit has been described. However, the present disclosure can be applied to embodiments other than the above example as long as the work device to which the work unit that performs the work for manufacturing the electronic circuit board is attached transmits the work history information to a plurality of devices. For example, an operation analysis device that determines operation analysis and an operation estimation device that estimates an operation situation may be used.

Note that, in the flow of the work device analysis method according to the exemplary embodiment of the present disclosure in FIG. 4, the order of a part of the flow may be changed. For example, in first file creation (ST2), statistical processing of the manufacturing log (ST3), and second file creation (ST4), ST2 may be executed after ST4. In addition, the order of maintenance necessity determination (ST5) of the work unit from the first file and estimation (ST6) of the state of the work unit from the second file may be reversed.

Note that, in the above description, the defined term is not limited only to the term. For example, the state of the work unit includes a sign of failure or a degree of risk, a degree of occurrence of the work mistake, a degree of deterioration, and the like.

In addition, maintenance necessity determination unit 67 may determine the maintenance necessity of the work units (tape feeder 16, mounting head 14, suction nozzle 15, and the like) including first file 65 stored in maintenance storage 64 and operation specified value data measured when each work unit is shipped or installed. Examples of the operation specified value data measured during shipment or installation include a flow rate value of flow rate sensor 14a when the component is sucked, a pressure value of the vacuum gauge when the component is sucked, and a current value when tape feeder 16 is operated.

### INDUSTRIAL APPLICABILITY

The work device analysis system, the work device analysis method, and the data collection device according to the present disclosure have an effect of appropriately analyzing the state of the work device, and are useful in the field of mounting electronic components on a board.

### REFERENCE MARKS IN THE DRAWINGS

1 work device analysis system
3 manufacturing management device (data collection device)
5 maintenance management device (maintenance necessity determination device, state estimation device)
14 mounting head (work unit)
15 suction nozzle (work unit)
16 tape feeder (work unit)
D component
M1 to M3 component mounting device (work device)

1. A work device analysis system comprising:
an acquisition unit that acquires work history information from a work device, the work device being attached with a work unit that performs a work for manufacturing an electronic circuit board;
a file generator that generates a first file and a second file from the work history information acquired, the first file including an operation event log of the work device, the second file including a manufacturing log of the electronic circuit board;
a maintenance necessity determination unit that determines maintenance necessity of the work unit based on the first file; and
a state estimation unit that estimates a state of the work unit based on the second file.

2. The work device analysis system according to claim 1, wherein the manufacturing log of the electronic circuit board includes a number of times of mounting mistakes of a component in the work device that mounts the component on the electronic circuit board.

3. The work device analysis system according to claim 1, wherein the manufacturing log of the electronic circuit board includes position deviation information from a normal holding position of the component held by a suction nozzle attached to the work device.

4. The work device analysis system according to claim 1, wherein
the acquisition unit further acquires mounting data to be used for the work in the work device, and
the file generator generates the second file further including a size of the component mounted on the electronic circuit board from the mounting data acquired.

5. The work device analysis system according to claim 1, wherein the file generator generates the second file by performing statistical processing on the manufacturing log of the electronic circuit board.

6. The work device analysis system according to claim 1, wherein the acquisition unit acquires the work history information while the work device is operating or at predetermined time intervals.

7. A work device analysis method comprising:
acquiring work history information from a work device, the work device being attached with a work unit that performs a work for manufacturing an electronic circuit board;
generating a first file and a second file from the work history information acquired, the first file including an operation event log of the work device, the second file including a manufacturing log of the electronic circuit board;
determining maintenance necessity of the work unit based on the first file; and
estimating a state of the work unit based on the second file.

8. The work device analysis method according to claim 7, wherein the manufacturing log of the electronic circuit board includes a number of times of mounting mistakes of a component in the work device that mounts the component on the electronic circuit board.

9. The work device analysis method according to claim 7, wherein the manufacturing log of the electronic circuit board includes position deviation information from a normal holding position of the component held by a suction nozzle attached to the work device.

10. The work device analysis method according to claim 7, further comprising:
further acquiring mounting data to be used for the work in the work device; and
generating the second file further including a size of the component mounted on the electronic circuit board from the mounting data acquired.

11. The work device analysis method according to claim 7, wherein the second file is generated by performing statistical processing on the manufacturing log of the electronic circuit board.

12. The work device analysis method according to claim 7, the work history information is acquired while the work device is operating or at predetermined time intervals.

13. A data collection device comprising:
an acquisition unit that acquires work history information from a work device, the work device being attached with a work unit that performs a work for manufacturing an electronic circuit board;
a file generator that generates a first file and a second file from the work history information acquired, the first file including an operation event log of the work device, the second file including a manufacturing log of the electronic circuit board; and
a transmission unit that transmits the first file and the second file.

14. The data collection device according to claim 13, wherein the manufacturing log of the electronic circuit board includes a number of times of mounting mistakes of a component in the work device that mounts the component on the electronic circuit board.

15. The data collection device according to claim 13, wherein the manufacturing log of the electronic circuit board includes position deviation information from a normal holding position of the component held by a suction nozzle attached to the work device.

16. The data collection device according to claim 13, wherein
the acquisition unit further acquires mounting data to be used for the work in the work device, and
the file generator generates the second file further including a size of the component mounted on the electronic circuit board from the mounting data acquired.

17. The data collection device according to claim 13, wherein the file generator generates the second file by performing statistical processing on the manufacturing log of the electronic circuit board.

18. The data collection device according to claim 13, wherein the acquisition unit acquires the work history information while the work device is operating or at predetermined time intervals.

19. The data collection device according to claim 13, wherein the transmission unit
transmits the first file to a maintenance necessity determination device that determines maintenance necessity of the work unit, and
transmits the second file to a state estimation device that estimates a state of the work unit.
